(19) United States
(12) Patent Application Publication
(10) Pub. No.: US 2025/0378867 A1
(43) Pub. Date: Dec. 11, 2025

(54) DRAM WITH MULTIPLE PER-BANK REFRESH ADDRESS COUNTERS

(71) Applicant: Peter Bruce Gillingham, Ottawa (CA)

(72) Inventor: Peter Bruce Gillingham, Ottawa (CA)

(73) Assignee: Patent Refinery Inc., Ottawa (CA)

(21) Appl. No.: 19/207,241

(22) Filed: May 13, 2025

Related U.S. Application Data
(60) Provisional application No. 63/657,115, filed on Jun. 6, 2024.

(51) Int. Cl. G11C 11/406

(52) U.S. Cl. CPC G11C 11/40618

(57) ABSTRACT

A Dynamic Random Access Memory (DRAM) includes a plurality of banks of memory that can be independently accessed and refreshed, and a plurality of refresh address counters each providing a refresh address to a respective bank. Per-bank refresh commands can be issued to any bank in any order, each refreshing a row in a single bank identified by the respective refresh address counter. An all-bank refresh command can be issued at any time to refresh rows in all banks identified by respective refresh address counters. A per-bank refresh command increments the respective refresh address counter while an all-bank refresh command increments all refresh address counters. Refresh address counters operate independently of each other and do not have to be synchronized in any way.

### CROSS REFERENCE TO RELATED APPLICATIONS

This application claims the benefit of priority of U.S. Provisional patent application Ser. No. 63/657,115 filed on Jun. 6, 2024, the contents of which are incorporated herein by reference in their entirety.

### BACKGROUND

Dynamic Random Access Memory (DRAM) is a commonly used volatile memory in widespread use as main memory in computer systems. FIG. 1 is a block diagram of a processor or System-On-Chip (SOC) 100 connected to a DRAM 110. DRAM 110 may be a single chip, multiple chips, or multiple chips assembled on a module. A memory controller 101 within SOC 100 communicates with DRAM 110 via a unidirectional n-bit wide command/address bus 120 and a bidirectional m-bit wide data bus 121. Command/address bus 120 may comprise separate dedicated connections for control information and address information or may comprise merged command and address connections that transfer both types of information.

Command/address bus 120 and data bus 121 together may be referred to as a memory channel. A single monolithic DRAM chip or die may have a single channel or multiple channels. Multiple channels in DRAM devices such as HBM (High Bandwidth Memory) access separate memory blocks independently. A single DRAM chip or die, or multiple DRAM chips and dice may be encapsulated in a single package comprising DRAM 110. Multiple DRAM chips and dice encapsulated in a single package may be connected in common to a single channel or connected independently to multiple channels. A single DRAM chip or die, or multiple DRAM chips and dice may be encapsulated together with SOC 100 in a single package.

Data stored within DRAM 110 is organized in rows and columns. To read information from or write information to DRAM 110 a row of memory within DRAM 110 must first be activated. Memory controller 101 activates a row by sending an activate command and a row address on command/address bus 120 to DRAM 110. The activate command and row address may be transferred in a single clock cycle or over several clock cycles. After the row is activated memory controller 101 may write a location in the activated row by sending a write command and a column address on command/address bus 120 and write data on data bus 121 to DRAM 110. The write command and column address may be provided simultaneously with the write data or in advance of the write data. After the row is activated memory controller 101 may also read a location in the activated row by sending a read command and a column address on command/address bus 120 to DRAM 110. After a certain amount of time required for the internal read operation DRAM 110 will send read data over data bus 121 to memory controller 101. Read and write data may comprise a single m-bit transfer or a burst of m-bit transfers over multiple clock cycles.

DRAM 110 must be periodically refreshed to preserve data stored therein. DRAM 110 includes a refresh counter 111 which keeps track of the rows to be refreshed. Typically multiple rows are refreshed in a single refresh operation. Memory controller 101 refreshes rows addressed by the current state of refresh counter 111 by sending a refresh command (also known as an auto-refresh command) on command/address bus 120 to DRAM 110. In response DRAM 110 activates corresponding rows to restore the data stored therein. DRAM 110 increments refresh counter 111 every time a refresh command is received so that every row is refreshed in sequence. Once DRAM 110 has been refreshed entirely, refresh counter 111 wraps around to begin refreshing from the start. Incrementing refresh counter 111 ensures that every possible refresh address is generated in sequence which can be accomplished by binary count up, binary count down, grey code count, or other methods. Memory controller 101 must issue refresh commands at a specified rate to ensure data remains uncorrupted.

When DRAM 110 is occupied performing an internal refresh operation it cannot respond to a read or write request from memory controller 101. Memory controller 101 must therefore wait for the completion of the internal refresh operation. As state of the art DRAM densities increase there are more rows to be refreshed and the percentage of time required for refresh operations becomes a significant fraction of the total remaining time available for actual read and write operations.

Modern DRAM devices include multiple banks that can be independently activated and deactivated. Multiple banks reduce the overhead associated with row operations because read and write data transfers can be directed to one bank while another bank is being activated or deactivated. However, multiple banks do not solve the refresh overhead problem because all banks are refreshed simultaneously with a single refresh command. Therefore all banks must be deactivated before a refresh command is issued. The power consumed in refreshing all banks simultaneously is also becoming a major issue, especially in low power portable applications.

Some more recent standards for DRAM devices such as DDR5 and LPDDR5 include a per-bank refresh command that refreshes rows in a subset of the banks while allowing other banks to remain active for data operations. In JEDEC DDR5 standard JESD79-5, which is incorporated herein by reference, this operation is called same-bank refresh (REFsb). All of the banks in a DDR5 chip can be refreshed as in previous generation DRAM devices by an all-bank refresh (REFab) command. JEDEC LPDDR5 standard JESD209-5 and JEDEC HBM3 standard JESD238, both of which are incorporated herein by reference, provide a per-bank refresh (REFpb) command which is substantially the same as REFsb in DDR5. All of the banks accessible through a single channel of a HBM3 or LPDDR5 device can be refreshed as in previous generation DRAM devices by an all-bank refresh (REFab) command. REFsb and REFpb reduce peak refresh power by distributing refresh operations more evenly over time.

A problem with REFsb and REFab in current devices is that the same refresh address in all of the banks must be refreshed before moving on to the next refresh address. The memory controller must keep track of which banks have been refreshed by a per-bank refresh command, either REFsb or REFpb, and insure that each bank is refreshed once and only once while the refresh counter within the DRAM is holding a given refresh address. This reduces the flexibility of the per-bank refresh scheme since an activated bank may have to be deactivated to allow refresh to proceed for another bank. Also, an inactive bank cannot be opportunistically refreshed in advance in anticipation of a period of intense activity. Furthermore, per-bank refresh requires significant overhead in the memory controller to schedule refresh commands.

### BRIEF DESCRIPTION OF THE DRAWINGS

FIG. 1 is a block diagram of a prior art DRAM memory system

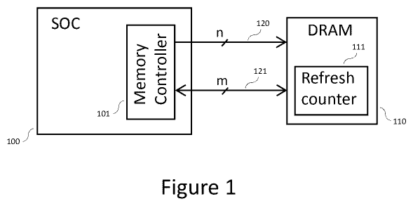

FIG. 2 is a table showing address fields for a representative 16 Gb DDR5 SDRAM device

FIG. 3 is a block diagram of a DRAM memory array and associated refresh circuitry with a single refresh address counter indicating a row activated in response to an activation command

FIG. 4 is a block diagram of a DRAM memory array and associated refresh circuitry with a single refresh address counter indicating rows activated in response to an all-bank refresh command

FIG. 5 is a block diagram of a DRAM memory array and associated refresh circuitry with a single refresh address counter indicating rows activated in response to a per-bank refresh command

FIG. 6 is a table showing a sequence of per-bank refresh and all-bank refresh commands applied to a DDR5 SDRAM and the resulting states of the bank counter and refresh address counter

FIG. 7 is a block diagram of a DRAM memory array and associated refresh circuitry with multiple refresh address counters indicating rows activated in response to a per-bank refresh command

FIG. 8 is a table showing a sequence of per-bank refresh and all-bank refresh commands applied to a DRAM having multiple refresh address counters and the resulting states of the refresh address counters

FIG. 9 is a table showing mode register definitions for read and write access to per-bank refresh address counters

### DETAILED DESCRIPTION

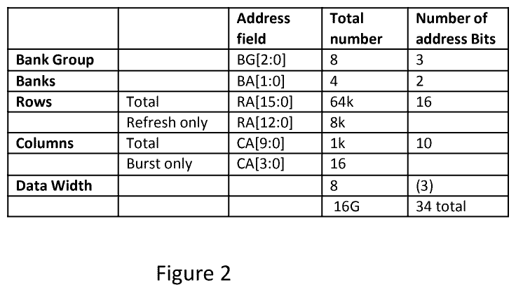

FIG. 2 summarizes addressing of a representative 16 Gb DDR5 SDRAM having an 8-bit data bus. Address fields BG[2:0], BA[1:0], RA[15:0], and CA[9:0] are provided by the memory controller to the DRAM over command/address bus 120. A 3-bit wide field BG[2:0] addresses one of 8 bank groups while a 2-bit wide field BA[1:0] addresses one of 4 banks within each bank group. A 16-bit row address field RA [15:0] addresses a single row among 64k rows within a selected bank. For an activate operation BG[2:0], BA[1:0], and RA[15:0] are provided by the memory controller along with the activate command to the DRAM over command/address bus 120, activating a single row in a selected bank. To deactivate or pre-charge a particular bank, BG[2:0] and BA[1:0] are provided by the memory controller along with the pre-charge command to the DRAM over command/address bus 120.

During a refresh operation eight rows are simultaneously activated. Therefore only 13 row address bits RA[12:0] are required in the refresh address counter for 8k (8192) refresh addresses. Since the refresh address is generated by the internal refresh address counter 110 the memory controller does not have to provide any address information when an all-bank refresh command is transferred over command/address bus 120. For a per-bank refresh command only BA[1:0] is required to select which one of the 4 banks within each of the bank groups is to be refreshed.

A 10-bit column address CA[9:0] indicates a block of 128-bits of data to be accessed in a column operation. A column operation is initiated in response to either a read command or a write command received on command/address bus 120. The least significant bits CA[3:0] of the column address indicate the starting address of the first 8-bit word in a 16-cycle data burst transferring the full 128-bit block of data. The same 128-bits of data are transferred regardless of CA[3:0]. Only the order within the burst is affected by CA[3:0]. For a read or write operation BG[2:0], BA[1:0], and CA[9:0] are provided by the memory controller along with the command to the DRAM over command/address bus 120.

The total number of actual address bits is 31, resulting in a 2G address space. If we consider 3 additional address bits to select any one of the individual bits in the 8-bit data bus, there is an effective total of 34 address bits allowing the full 16 Gb memory to be addressed (2**34=16G).

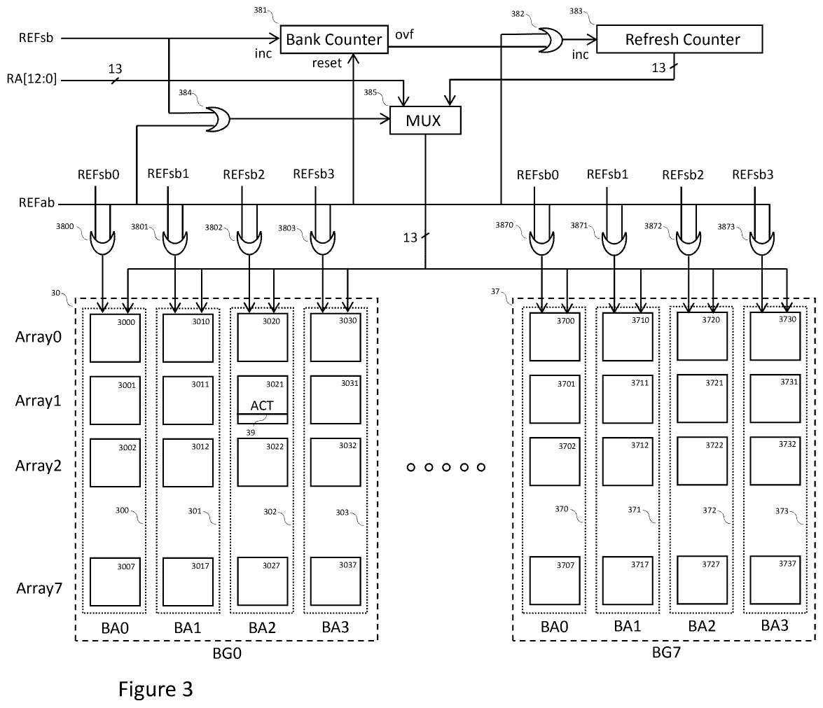

FIG. 3 is a high level block diagram of the memory arrays and refresh circuits of a representative 16 Gb (x8) DDR5 SDRAM chip. There are 8 Bank Groups BG0 30 to BG7 37. Only Bank Groups BG0 30 and BG7 37 are actually shown here for brevity. The remaining bank groups BG1 to BG6 are identical. Within each bank group there are 4 individual banks BA0 3x0 to BA3 3x3, where x is the bank group number. Within each bank there are 8 logical arrays Array0 3xy0 to Array7 3xy7, where x is the bank group number and y is the bank number. Only 4 arrays, Array0 3xy0, Array1 3xy1, Array2 3xy2, and Array7 3xy7, are actually shown here. The remaining arrays Array3, Array4, Array5, and Array6 are identical.

Refresh circuitry comprises a 2-bit binary bank address counter 381, a 2-input OR gate 382, a 13-bit binary refresh address counter 383, a 2-input OR gate 384, a 13-bit multiplexer 385, and 2-input OR gates 38xy, where x is the bank group number and y is the bank number indicating to which one of the 32 banks 3xy the output of a particular OR gate 38xy is connected. The refresh circuitry shown is simplified for purposes of illustration. For example an OR gate may actually be implemented as a NOR gate followed by an inverter. Circuitry required for activate, pre-charge, read and write operations are not shown.

Inputs to the refresh circuitry include REFsb which is a single bit activated when a same-bank or per-bank refresh command is received over command/address bus 120. RA[12:0] is part of the row address provided over command/address bus 120 along with an activate command. REFab is a single bit input activated when an all-bank refresh command is received. One of four inputs REFsb0, REFsb1, REFsb2, and REFsb3 is activated depending on BA[1:0] when a same-bank or per-bank refresh command is received over command/address bus 120.

Since the focus of the invention is per-bank refresh, many inputs to the banks required for other operations are not shown. For example row addresses RA [15:13], column addresses CA[9:0], bank group addresses BG[2:0] and bank addresses BG[1:0] inputs to the banks are not shown. Many other signals required for DRAM operation, including word line and sense amplifier activation signals, pre-charge signals, and bit line equalization signals are omitted as well.

Logical arrays Array0 3xy0 to Array7 3xy7 may be further subdivided into physical arrays to optimize electrical performance. Data in a DRAM cell is stored as charge in a memory cell capacitor. When a row is activated the stored charge is dumped onto a bit line that is shared with many other memory cells. The cell charge is attenuated by the ratio of cell capacitance to bit line capacitance. To limit the bit line capacitance and permit reliable sensing of the attenuated charge, the number of cells sharing a single bit line is typically limited, for example to 512.

For high speed operation the length of a physical word line or row may have to be limited to several thousand memory cells in order to mitigate the effects of RC delay along the word line. For example, with 512 cells connected to each bit line and 2k cells connected to each word line or row, the size of one physical array would be 1 Mb (512×2k). Since a logical array has 8k rows and 8k bits (1k column addresses x 8 bits) on each row for a total capacity of 64 Mb (8k×8k), there would be a total of 64 physical arrays in each logical array.

FIG. 3 shows a single word line or row 39 activated in logical array 3021 within bank 302 in bank group 30 in response to an activate (ACT) command. Only one logical array 3021 is activated. The other logical arrays 3020 and 3022-2027 within bank 302 remain inactive. Further activate commands may turn on one word line in every other bank, but only one word line can be activated within any one bank. Word line 39 is activated in response to input RA[15:0] received along with the activate command. RA[15:13] is provided directly from the command decoder to banks 3xy (not shown). RA[12:0] passes through multiplexer 385 before reaching the bank.

During an activate operation, both input signals REFsb and REFab will be inactive (logic ‘0’) so that the output of OR gate 384, which drives the select input of multiplexer 385, will be logic ‘0’. The left side multiplexer input is selected and RA [12:0] is provided at the 13-bit output of multiplexer 385 and from there connected to the refresh address input of all banks 3xy. The activate command itself is provided along with bank group address BG[2:0] and bank address BA[1:0] to all banks 3xy (not shown) so that the appropriate word line 39 in the selected bank 302 is activated.

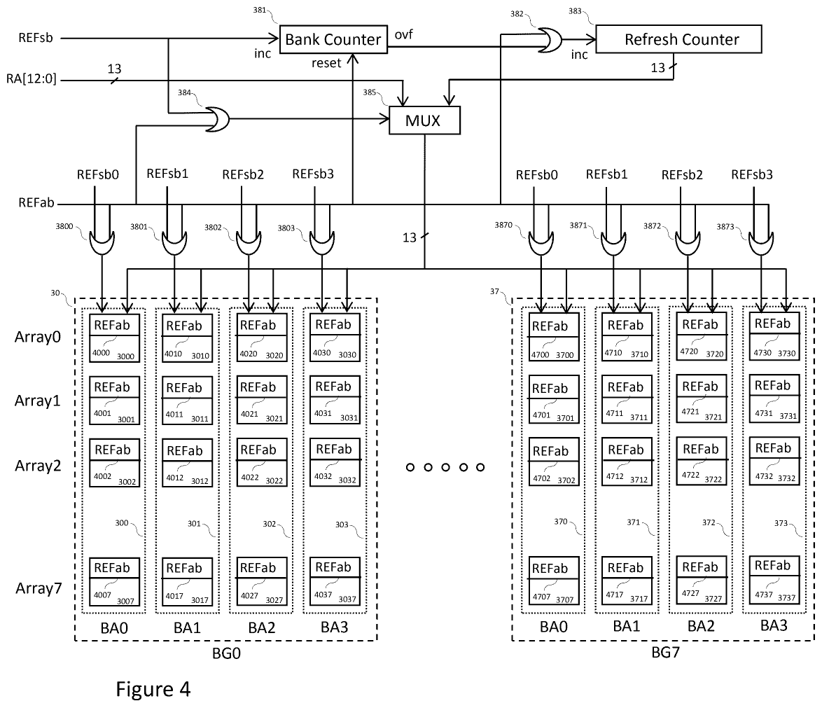

FIG. 4 is a high level block diagram of the memory arrays and refresh circuits of a representative 16 Gb (x8) DDR5 SDRAM chip identical to FIG. 3 with the exception that multiple activated rows are shown as the response to an all-bank refresh command. A single row is activated within every logical array. Word lines 4xyz are activated in all logical arrays 3xyz within all banks 3xy in all bank groups 3x, where x is the bank group number, y is the bank number, and z is the logical array number. A REFab command typically requires more time than a single row activation command (ACT) because arrays may be sequentially activated to limit peak power consumption. REFab also consumes more power than an ACT command. The address of the word lines activated by REFab is provided by refresh address counter 383. Each REFab command increments refresh address counter 383 so that on a subsequent REFab command the next word lines in each array will be refreshed.

At the start of the all-bank refresh operation, input signal REFab will transition from an inactive state (logic ‘0’) to an active state (logic ‘1’) while input signal REFsb remains inactive (logic ‘0’). As a result, the output of OR gate 384, which drives the select input of multiplexer 385, will be logic ‘1’. The right side multiplexer input is selected and the output of refresh counter 383 is provided at the 13-bit output of multiplexer 385 and from there connected to the refresh address input of all banks 3xy. Furthermore, the activated REFab signal will force the output of all OR gates 38xy connected to the refresh command input of all banks 3xy to logic ‘1’. As a result, each bank 3xy will latch the refresh address input and initiate a refresh operation at the address specified by refresh counter 383. After the refresh operation begins, input signal REFab transitions back to the inactive state (logic ‘O’).

At the start of the all-bank refresh operation the output of OR gate 382 will transition from logic ‘0’ to logic ‘1’ as a result of the activation of the REFab input signal. At the same time REFab connected to the reset input of bank counter 381 will force this 2-bit bit counter to 0. Once refresh operations are initiated in each of the banks, the output of OR gate 382 will transition from logic ‘1’ to logic ‘0’ as a result of the deactivation of the REFab input signal. The output of OR gate 382 is connected to the negative edge triggered increment input of refresh address counter 383. With the logic ‘1’ to logic ‘0’ transition at the output of OR gate 382 after refresh addresses have been latched in each of the banks, the 13-bit value stored in refresh address counter 383 will be incremented by 1. If the value stored in refresh address counter 383 is the maximum count value 8191 the count will wrap around to 0.

During a REFab operation the memory cannot be accessed since every bank in every bank group is busy performing refresh. Typically the entire memory must be refreshed within a 32 ms period if the temperature is below a certain limit. With 8192 (8k) refresh addresses this means that a REFab command should be issued roughly every 4 us. JESD79-5 allows up to 4 REFab commands to be postponed to allow high priority memory accesses to occur without delay due to regularly scheduled refresh operations. A maximum time between 2 successive REFab commands is therefore 20 us.

Some DRAM devices such as DDR5 also provide a fine granularity refresh mode, in which fewer rows are refreshed at a time but refresh commands must be issued more frequently. This has the benefit of lower peak power consumption at the cost of higher command/address bus utilization overhead for refresh. If the example device in FIG. 4 is programmed to operate in fine granularity refresh mode, then a REFab command would have to be issued once every 2 us to fully refresh 16344 (16k) addresses within the 32 ms period. In this mode, refresh address counter 383 should be reprogrammed to output a 14-bit value to the banks 3xy. Only half of logical arrays 3xyz should then be activated by a single REFab command. For example, for even values of the 14-bit refresh address logical arrays 3xy0, 3xy2, 3xy4, and 3xy6 could be activated, while for odd values of the 14-bit refresh address logical arrays 3xy1, 3xy3, 3xy5, and 3xy7 could be activated. Instead of reprogramming the width of refresh address counter 383 depending on whether normal or fine granularity is desired, the width could be fixed at 14-bits and 2 internal refresh cycles would triggered by a single REFab command in normal refresh mode, while a single internal refresh cycle would be triggered in fine granularity refresh mode. For brevity and to facilitate explanation of the inventive concepts, circuitry supporting programmable refresh granularity is not shown in the figures.

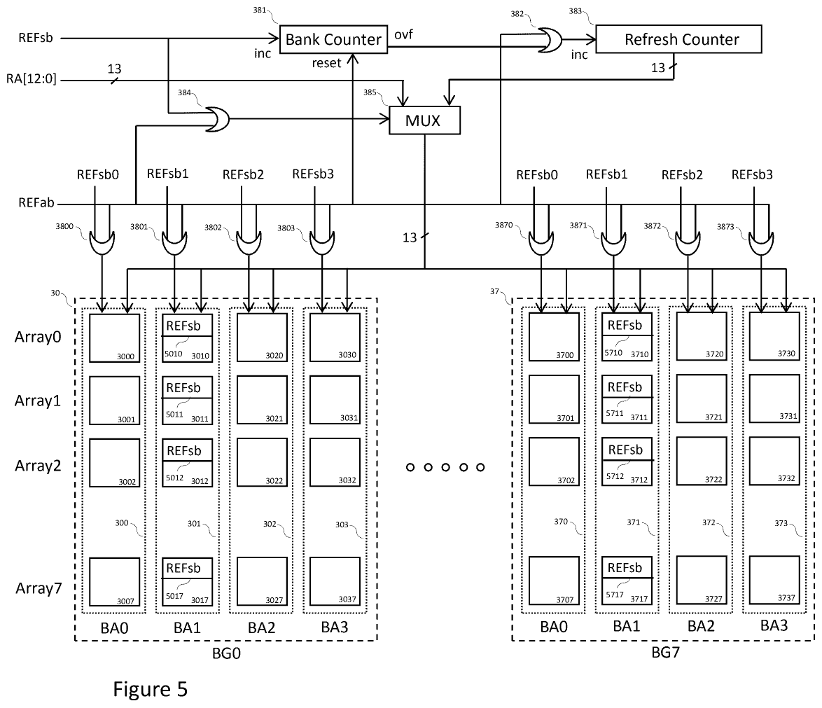

FIG. 5 is a high level block diagram of the memory arrays and refresh circuits of a representative 16 Gb (x8) DDR5 SDRAM chip identical to FIG. 3 with the exception that multiple activated rows are shown as the response to a per-bank refresh command (REFpb or REFsb). A single row is activated within every logical array of a selected bank within each bank group. In this example the selected bank in the per-bank refresh command is BA1. Word lines 5x1z are activated in logical arrays 3x1z within bank 3x1 in all bank groups 3x, where x is the bank group number and z is the logical array number. A REFpb/sb command also consumes less power than a REFab command because fewer arrays are activated. The address of the word lines activated by REFpb/sb is provided by refresh address counter 383.

At the start of the per-bank refresh operation, input signal REFsb will transition from an inactive state (logic ‘0’) to an active state (logic ‘1’) while input signal REFab will remain inactive (logic ‘0’). As a result, the output of OR gate 384, which drives the select input of multiplexer 385, will be logic ‘1’. The right side multiplexer input is selected and the output of refresh counter 383 is provided at the 13-bit output of multiplexer 385 and from there connected to the refresh address input of all banks 3xy. In addition, REFsb1 will be activated (logic ‘1’) since bank BA1 is selected while REFsb0, REFsb2, and REFsb3 remain deactivated (logic ‘0’). This will force the output of OR gates 38x1 connected to the refresh command input of banks 3x1 to logic ‘1’. As a result, one bank 3x1 in each bank group will latch the refresh address input and initiate a refresh operation at the address specified by refresh counter 383. After the refresh operation begins, input signals REFsb and REFsb1 transition back to the inactive state (logic ‘0’).

Once refresh operations are initiated in the selected banks, input signal REFsb connected to the negative edge triggered increment input of bank counter 381 will transition from active (logic ‘1’) back to inactive (logic ‘0’). The transition will cause bank counter 381 to increment by 1. If the value stored in bank counter 381 is the maximum count value 3 the count will wrap around to 0. When the value stored in bank counter 381 is the maximum count value 3, the overflow flag output of bank counter 381 will be active (logic ‘1’). When the count wraps around to zero there will be a logic ‘1’ to logic ‘0’ transition on the overflow flag output. This transition will pass through OR gate 382 to increment refresh address counter 383. Thus refresh address counter 383 is incremented after completion of four per-bank refresh operations.

Per-bank refresh operation allows refresh of some banks while other banks remain available for read and write operations. In this example bank BA1 is being refreshed but banks BA0, BA2, and BA3 could be accessed by activate, read or write commands. Further per-bank refresh commands may turn on word lines in banks BA0, BA2, and BA3, even before the per-bank refresh operation in bank BA1 has completed. The JEDEC DDR5 SDRAM standard requires a sequence of 4 REFsb commands to all 4 banks in any order.

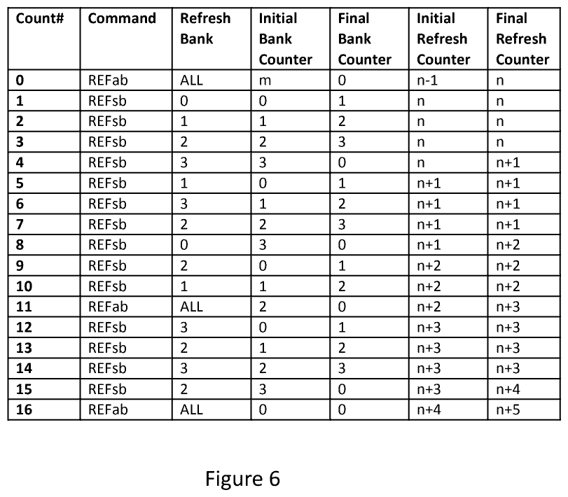

FIG. 6 illustrates a sequence of REFab and REFsb commands to a memory device conforming to the DDR5 specification and the resulting states of bank counter 381 and refresh address counter 383. At each step a per-bank refresh command (REFsb) to a particular bank or an all-bank refresh command (REFab) is issued. The initial and final states of bank counter 381 and refresh address counter 383 are shown. A REFab command will reset bank counter 381 to 0. With each REFsb operation bank counter 381 is incremented. If bank counter 381 wraps around from 3 to 0, refresh address counter 383 is incremented. Refresh address counter 383 is also incremented at the end of each REFab operation.

On count 0 a REFab command refreshes row n−1 in all banks, resets the bank counter 381 and increments the refresh address counter 383 to n. Four subsequent REFsb commands to banks 0, 1, 2, and 3 on counts 1˜4 refresh row n in all banks and increment refresh address counter 383 to n+1. Four more REFsb commands on counts 5-8 to banks 1, 3, 2 and 0 refresh row n+1 in all banks and increment refresh address counter 383 to n+2. The order of bank refresh in each sequence of 4 REFsb commands does not matter as long as each bank is refreshed once in each sequence.

At counts 9-10 another sequence of REFsb commands is initiated to refresh row n+2 in banks 2 and 1 but a REFab command is issued on count 11 before all 4 banks had been refreshed. Because bank counter 381 has not wrapped around refresh address counter 383 has not yet been incremented and banks 1 and 2 will be refreshed a second time at the same refresh address n+2 by the REFab command. Although this operation is permitted by the DDR5 specification and does ensure that all rows in each bank are properly refreshed at least once, it does represent wasted power and command bandwidth since the same refresh addresses are refreshed twice and the two REFsb commands at counts 9 and 10 serve no useful purpose.

The sequence of REFsb commands in counts 12-15 is not permitted by the DDR5 specification but illustrates how an improperly controlled DDR5 SDRAM may fail to refresh all rows. In the sequence of counts 12-15, banks 2 and 3 are both refreshed twice at row n+3 but banks 0 and 1 are not refreshed at all. Since a sequence of 4 REFsb commands was received, bank counter 381 will wrap around and refresh address counter 383 will increment to n+4. Refresh of row n+3 in banks 0 and 1 is bypassed and data retention failures may occur at these locations.

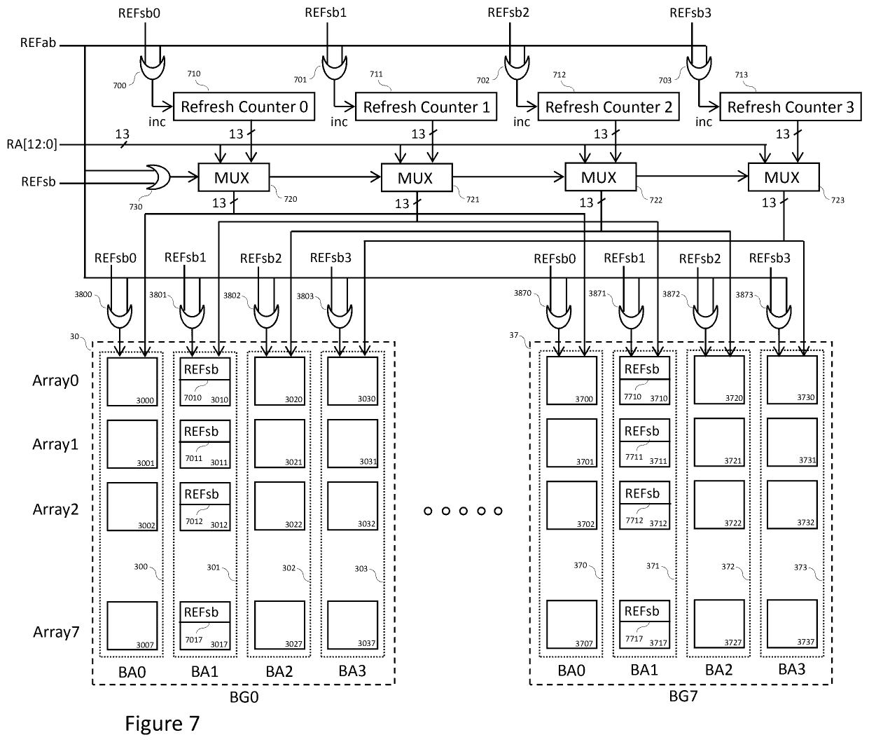

FIG. 7 is a high level block diagram of the memory arrays and refresh circuits of a DRAM chip having a dedicated refresh address counter for each bank. The memory arrays are organized identically to those shown in FIG. 3 with 8 bank groups BG0 30 to BG7 37 and 4 banks BA0 3x0 to BA3 3x3 within each bank group. Within each bank there are 8 logical arrays Array0 3xy0 to Array7 3xy7, where x is the bank group number and y is the bank number. Inputs REFab, RA [12:0], REFsb, REFsb0, REFsb1, REFsb2 and REFsb3 are likewise identical and perform the same functions as those in FIG. 3. Also identical to FIG. 3 are OR gates 38xy having inputs connected to REFab and REFsby and output connected to the refresh command input of all banks 3xy.

Improved refresh circuitry comprising four 2-input OR gates 70y, four 13-bit binary refresh address counters 71y, four 13-bit multiplexers 72y, and a 2-input OR gate 730 allow each bank to be refreshed independently of other banks. Outputs of OR gates 70y are connected to the negative edge triggered inputs of refresh address counters 71y to increment the refresh address following an all-bank refresh operation REFab or a per-bank refresh operation REFsb to bank BAy.

The output of OR gate 730 is activated to a logic ‘1’ level whenever a per-bank refresh command REFsb or an all-bank refresh command REFab is received. The output of OR gate 730 is connected to the select input of all four multiplexers 72y. The output of refresh address counter 71y is provided to the right side input of multiplexers 72y, while RA[12:0] from a received activation command is provided to the left side input. Multiplexers 72y outputs are connected to the refresh address input of all banks 3xy to provide the 13-bit address from refresh address counter 71y during a per-bank refresh REFsb or an all-bank refresh REFab operation. At other times, such as during an activation operation, multiplexers 72y outputs will provide the externally received row address RA[12:0].

FIG. 7 shows rows 7x1z activated in all logical arrays 3x1z in bank 3x1 in every bank group 3x, where x is the bank group number and z is the logical array number, in response to a per-bank refresh REFsb command directed to bank BA1. Active (logic ‘1’) input signal REFsb forces the output of OR gate 730 to logic ‘1’ so that multiplexer 721 selects the output of refresh counter 711 for the refresh address input of banks 3x1. Once refresh addresses are latched and refresh operations are initiated in the selected banks, REFsb1 will transition from active (logic ‘1’) to inactive (logic ‘0’). This transition passes through OR gate 701 to the negative edge triggered increment input of refresh address counter 711. Thus refresh address counter 711 is incremented after the start of a per-bank refresh operation in BA1. The other refresh address counters 710, 712, and 713 associated with banks BA0, BA2, and BA3 respectively are not incremented as a result of the per-bank refresh operation directed to BA1.

While the per-bank refresh operation is in progress in bank BA1, per-bank refresh operations can be initiated or already in progress in other banks. Likewise, activate, precharge, read, or write operations can be initiated or already in progress in other banks while the per-bank refresh operation is in progress in bank BA1. An all-bank refresh operation cannot be initiated until the per-bank refresh operation in bank BA1 is completed.

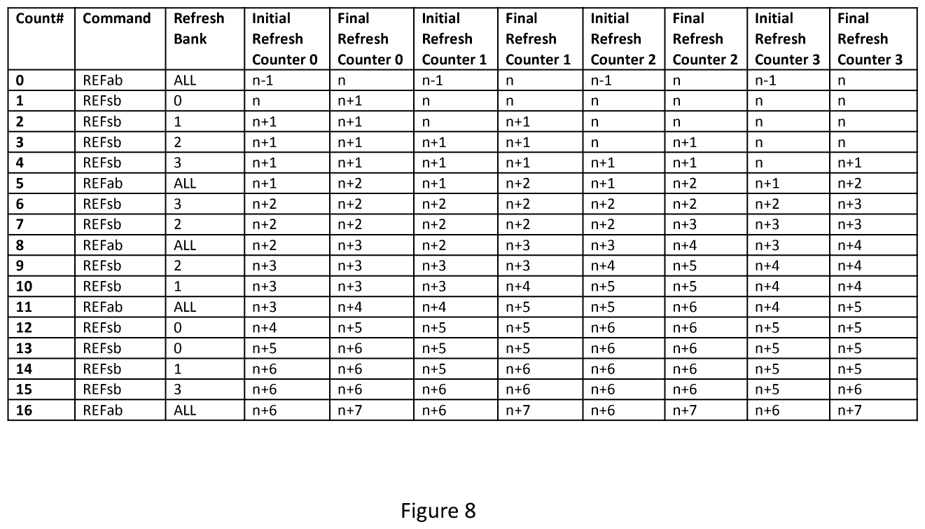

FIG. 8 illustrates a sequence of REFab and REFsb commands to a memory device having a dedicated refresh address counter for each bank as shown in FIG. 7, and the resulting states of refresh address counters 710, 711, 712, and 713. At each step a per-bank refresh command (REFsb) to a particular bank or an all-bank refresh command (REFab) is issued. For better understanding it is assumed that each operation is completed before the command for the next operation is issued. The initial and final states of refresh address counters 710, 711, 712, and 713 are shown. After the start of each REFsb operation in a particular bank BAy, refresh address counter 71y associated with that bank is incremented. All refresh address counters 710, 711, 712, and 713 are incremented at the end of each REFab operation.

In the beginning all refresh address counters have stored value of n−1. On count 0 a REFab command refreshes row n−1 in all banks and increments all refresh address counters 710, 711, 712, and 713 to n. Four subsequent REFsb commands to banks 0, 1, 2, and 3 on counts 1-4 sequentially refresh row n in all banks and increment all refresh address counters 710, 711, 712, and 713 to n+1. A REFab command on count 5 simultaneously refreshes row n in all banks and increments all refresh address counters 710, 711, 712, and 713 to n+2.

On counts 6-7 a REFsb command is issued to banks 3 and 2. Row n+2 is refreshed in each of these banks and refresh address counters 712 and 713 are incremented to n+3. Banks 0 and 1 are not refreshed and their associated refresh address counters 710 and 711 are not incremented. On count 8 a REFab command is issued so that row n+2 of banks 0 and 1, and row n+3 of banks 2 and 3 will be refreshed. Refresh address counters 710 and 711 associated with banks 0 and 1 are incremented to n+3 while refresh address counters 712 and 713 associated with banks 2 and 3 are incremented to n+4.

On counts 9-10 a REFsb command is issued to banks 2 and 1. Row n+4 is refreshed in bank 2 and row n+3 is refreshed in bank 1. Refresh address counters 711 is incremented to n+4 and refresh address counters 712 is incremented to n+5. At this point the refresh address counters 710, 711, 712, and 713 are out of synchronization. The memory controller may strive over the long term to keep the refresh counters substantially synchronized. To re-synchronize in this particular example two REFsb commands can be issued to bank 0 and a single REFsb command can be issued to banks 1 and 3 as shown in counts 12-15. These operations refresh rows in banks 0, 1, and 3 and advance refresh address counters 710, 711 and 713 to count values equal to that of refresh address counter 712, namely n+6.

On average a REFab command should be issued every 4 us. Alternatively, a REFsb command should be issued to each bank during each 4 us interval. During periods of high read and write activity the controller may postpone a certain number of refresh commands. Also during periods of low read and write activity the controller may advance a certain number of refresh commands in anticipation of a future high read and write activity period. As an example up to 4 REFab or REFsb commands to any single bank could be postponed or advanced.

With the refresh circuit of FIG. 7 there are no duplicated refresh operations when sequences of 4 REFsb operations to the 4 banks are interrupted with a REFab command. This saves power and avoids congestion on the command/address bus due to unnecessary REFsb commands, thereby allowing more useful activate, read, and write commands to be issued. REFsb commands can be issued in any arbitrary order so that the memory controller does not have to ensure that every bank is refreshed in a sequence of 4 REFsb commands. The memory controller need not refresh all banks in a synchronized fashion or at the same rate. For example, if a particular bank is not being used, refresh to that bank may be suspended to save power.

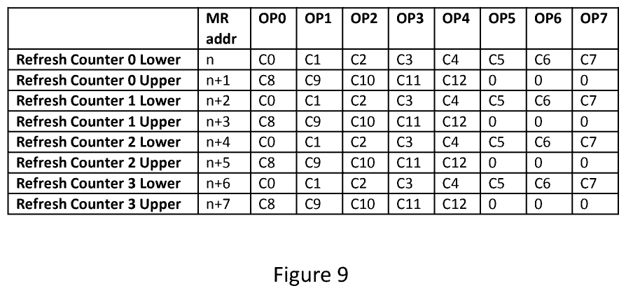

The ability for the memory controller to read the values in the refresh counters facilitates keeping track of the state of refresh in all banks of the DRAM. Modern DRAM devices such as DDR5 and LPDDR5 support mode register read (MRR) operations. Additional mode register space can be added as shown in FIG. 9 to allow the per-bank refresh address counters to be read in a mode register read operation. As shown, the 13 bits C0 to C12 of each of the refresh address counters 710, 711, 712, and 713 are provided through two Mode Register Read operations, lower 8-bit read for C0 to C7 and an upper 5-bit read for C8 to C12.

The same registers can also support a Mode Register Write (MRW) feature allowing the controller to set or reset any or all of refresh address counters 710, 711, 712, and 713. Resetting to zero is accomplished by writing ‘00000000’ to both upper and lower locations. Alternatively, a special command such as a Multi-Purpose Command (MPC) could be used to reset refresh address counters 710, 711, 712, and 713. Preferably, a single MPC command resets both upper and lower portions of a per-bank refresh address counter. A hardware reset via the reset pin (not shown) can also be used to reset refresh address counters 710, 711, 712, and 713 to zero.

1. A dynamic random access memory (DRAM) device comprising:
an interface for receiving command and address information,
a plurality of memory banks, and
a plurality of refresh address counters each associated with one of the plurality of memory banks,
wherein upon receiving at the interface a per-bank refresh command directed to a selected one of the memory banks, memory locations in the selected one of the memory banks addressed by an associated one of the refresh address counters are refreshed, and the associated one of the refresh address counters is incremented.

2. The DRAM device as claimed in claim 1, wherein upon receiving at the interface an all-bank refresh command, memory locations in each of the memory banks addressed by associated ones of the refresh address counters are refreshed, and each one of the plurality of refresh address counters are incremented.

3. The DRAM device as claimed in claim 1, further comprising a plurality of memory bank groups, wherein a first memory bank group includes the plurality of memory banks and each of the plurality of memory bank groups other than the first memory bank group includes an additional plurality of memory banks each associated with one of the plurality of refresh address counters, wherein upon receiving the per-bank refresh command, memory locations in the selected ones of the additional memory banks addressed by the associated one of the refresh address counters are refreshed.

4. The DRAM device as claimed in claim 1, wherein the associated one of the refresh address counters is incremented after refresh of memory locations in the selected one of the memory banks addressed by the associated one of the refresh address counters is initiated.

5. The DRAM device as claimed in claim 1, wherein the interface is a selected one of a double-data-rate synchronous DRAM (DDR SDRAM) interface, a low-power double-data-rate synchronous DRAM (LPDDR SDRAM) interface, or a high-bandwidth-memory DRAM (HBM DRAM) interface.

6. The DRAM device as claimed in claim 1, further comprising a package encapsulating the dynamic random access memory device.

7. The DRAM device as claimed in claim 6, further comprising within the package an additional DRAM device sharing the interface for receiving command and address information.

8. The DRAM device as claimed in claim 6, further comprising within the package an additional DRAM device having an additional interface for receiving command and address information.

9. The DRAM device as claimed in claim 6, further comprising within the package a system-on-chip (SOC) device having a memory controller providing command and address information to the DRAM device through the interface.

10. The DRAM device as claimed in claim 1, further comprising an additional interface for receiving additional command and address information, an additional plurality of memory banks, and an additional plurality of refresh address counters each associated with one of the additional plurality of memory banks, wherein upon receiving at the additional interface an additional per-bank refresh command directed to a selected one of the additional memory banks, additional memory locations in the selected one of the additional memory banks addressed by an associated one of the additional refresh address counters are refreshed, and the associated one of the additional refresh address counters is incremented.

11. A method for controlling a dynamic random access memory (DRAM) device having a plurality of memory banks and a plurality of refresh address counters each associated with one of the plurality of memory banks comprising:
issuing to the DRAM device a first number of per-bank refresh commands for selected one or ones of the memory banks not including a first memory bank, wherein the first number is greater than or equal to the number of memory banks,
wherein rows in the selected one or ones of the memory banks not including the first memory bank are refreshed by each of the per-bank refresh commands, and no rows in any of the plurality of memory banks are refreshed more than once.

12. The method for controlling a DRAM device as claimed in claim 11 further comprising:
issuing to the DRAM device an all-bank refresh command,
wherein a single row in each bank of the plurality of memory banks is refreshed by the all-bank refresh command and no rows in any of the plurality of memory banks are refreshed more than once.

13. The method for controlling a DRAM device as claimed in claim 12 wherein the all-bank refresh command is issued after all of the first number of per-bank refresh commands have been issued.

14. The method for controlling a DRAM device as claimed in claim 12 wherein the all-bank refresh command is issued before any of the first number of per-bank refresh commands have been issued.

15. The method for controlling a DRAM device as claimed in claim 12 wherein the all-bank refresh command is issued after a second number of per-bank refresh commands have been issued and before a third number of per-bank refresh commands have been issued, wherein the first number is equal to the sum of the second number and the third number.

16. The method for controlling a DRAM device as claimed in claim 11 further comprising issuing to the DRAM a mode register read (MRR) command to read a selected one of the plurality of refresh address counters.

17. The method for controlling a DRAM device as claimed in claim 16 further comprising issuing to the DRAM an additional MRR command to read the selected one of the plurality of refresh address counters, wherein the MRR command reads a lower portion of the selected one of the plurality of refresh address counters and the additional MRR command reads an upper portion of the selected one of the plurality of refresh address counters.

18. The method for controlling a DRAM device as claimed in claim 11 further comprising issuing to the DRAM a mode register write (MRW) command to write a selected one of the plurality of refresh address counters.

19. The method for controlling a DRAM device as claimed in claim 18 further comprising issuing to the DRAM an additional MRW command to write the selected one of the plurality of refresh address counters, wherein the MRW command writes a lower portion of the selected one of the plurality of refresh address counters and the additional MRW command writes an upper portion of the selected one of the plurality of refresh address counters.

20. The method for controlling a DRAM device as claimed in claim 11 further comprising issuing to the DRAM a multi-purpose command (MPC) to reset a selected one of the plurality of refresh address counters.
